(19) United States
(12) Patent Application Publication
(10) Pub. No.: US 2014/0104452 A1
(43) Pub. Date: Apr. 17, 2014

(54) SUB-PIXELS, IMAGE SENSORS HAVING THE SAME AND IMAGE SENSING SYSTEMS

(71) Applicant: SAMSUNG ELECTRONICS CO., LTD., Suwon-Si (KR)

(72) Inventors: Tae Chan KIM, Yongin-si (KR); Min Ho KIM, Seongnam-si (KR); Dong Ki MIN, Seoul (KR); Sang Chul SUL, Suwon-si (KR); Tae Seok OH, Seoul (KR); Kwang Hyun LEE, Seongnam-si (KR); Tae Yon LEE, Seoul (KR); Jae Jin JUNG, Seoul (KR); Young Gu JIN, Osan-si (KR)

(73) Assignee: SAMSUNG ELECTRONICS CO., LTD., Suwon-Si (KR)

(21) Appl. No.: 13/828,591

(22) Filed: Mar. 14, 2013

Related U.S. Application Data
(60) Provisional application No. 61/713,175, filed on Oct. 12, 2012.

(30) Foreign Application Priority Data
Feb. 19, 2013 (KR) 10-2013-0017560

(51) Int. Cl. H01L 31/02; H01L 27/146; H04N 5/232

(52) U.S. Cl. CPC H01L 31/02016; H04N 5/23229; H01L 27/14609
USPC 348/222.1; 250/206; 250/208.1

(57) ABSTRACT

A sub pixel includes a photodetector and a column line output circuit. The photodetector is configured to output an electrical signal based on a detected amount of photons. The column line output circuit is configured to generate an output signal based on the electrical signal. The output signal is one of a current from a current source and a comparison signal indicative of binary output data.

### CROSS-REFERENCE TO RELATED APPLICATIONS

This application claims priority under 35 U.S.C. §119(e) to U.S. provisional patent application No. 61/713,175 filed on Oct. 12, 2012, and under 35 U.S.C. §119 to Korean Patent Application No. 10-2013-0017560, filed Feb. 19, 2013, in the Korean Intellectual Property Office, the entire contents of each of which are hereby incorporated herein by reference.

### BACKGROUND

1. Field

Example embodiments of inventive concepts relate to image sensors, and more particularly, sub pixels, image sensors having the same, and image sensing systems.

2. Description of the Related Art

A related art complementary metal-oxide-semiconductor (CMOS) image sensor includes pixels that collect and integrate a plurality of photoelectrons. As the pixels become smaller in size, problems may arise. For example, deterioration of image quality may occur due to fewer photoelectrons. In addition, color cross-talk may become a problem.

### SUMMARY

At least one example embodiment is directed to a sub pixel including: a photodetector configured to detect an amount of photons, and output an electrical signal corresponding to photoelectrons generated by the detected photons; and a comparator configured to compare a threshold signal with the electrical signal and output a comparison signal according to a result of the comparison.

According to at least some example embodiments, the sub pixel may further include: a counter configured to count the comparison signal. The sub pixel may further include: a selection switch configured to output the comparison signal in response to a selection signal. The comparator may detect one photon output from the photodetector according to a value of the threshold signal.

At least one other example embodiment is directed to an image sensor including: a sub pixel array; and a counter configured to count the comparison signal output from the sub pixel. The sub pixel array includes at least one sub pixel having: a photodetector configured to detect an amount of photons generated by the detected photons, and output an electrical signal corresponding to photoelectrons; and a comparator configured to compare a threshold signal with the electrical signal, and output a comparison signal according to a result of the comparison.

According to at least some example embodiments, the image sensor may further include: a memory configured to store a counter value output from the counter; and a read out circuit configured to control the memory to output the counter value. The sub pixel array and the counter may be embodied in different wafers.

At least one other example embodiment is directed to an image sensing system including: an image sensor; and an image signal processor configured to process a signal output from the image sensor. The image sensor includes: a sub pixel array; and a counter configured to count the comparison signal output from the sub pixel. The sub pixel array includes at least one sub pixel having: a photodetector configured to detect an amount of photons, and output an electrical signal corresponding to photoelectrons generated by the detected photons; and a comparator configured to compare a threshold signal with the electrical signal and output a comparison signal according to a result of the comparison. The image sensing system may be a smart phone or a tablet PC.

At least one other example embodiment is directed to a sub pixel including: a photodetector configured to detect an amount of photons and output an electrical signal corresponding to photoelectrons generated by the detected photons; a current source configured to generate a current; and a control circuit configured to output the current in response to the electrical signal.

At least one other example embodiment is directed to an image sensor including: a sub pixel array including at least one sub pixel; and an analog to digital converter configured to convert the current, output from the sub pixel, to a digital signal. The sub pixel includes: a photodetector configured to detect an amount of photons and output an electrical signal corresponding to photoelectrons generated by the detected photons; a current source configured to generate a current; and a control circuit configured to output the current in response to the electrical signal. The sub pixel array and the analog to digital converter may be embodied in different wafers.

At least one other example embodiment is directed to an image sensing system including: an image sensor; and an image signal processor configured to process a signal output from the image sensor. The image sensor includes: a sub pixel array including at least one sub pixel; and an analog to digital converter configured to convert the current output from the sub pixel to a digital signal. The sub pixel includes: a photodetector configured to detect an amount of photons and output an electrical signal corresponding to photoelectrons generated by the detected photons; a current source configured to generate a current; and a control circuit configured to output the current in response to the electrical signal. The image sensing system may be a smart phone or a tablet PC.

At least one other example embodiment is directed to a sub pixel including: a photodetector configured to output an electrical signal based on a detected amount of photons; and a column line output circuit configured to generate an output signal based on the electrical signal, the output signal being one of a current from a current source and a comparison signal indicative of binary output data.

According to at least some example embodiments, the sub pixel may further include: a counter coupled between the column output circuit and a column line, and configured to count the comparison signal.

According to at least some example embodiments, the sub pixel may further include: a selection switch coupled between the column line output circuit and a column line. The selection switch may be configured to output the output signal in response to a selection signal. A reset switch may be coupled between the photodetector and the column line output circuit. The reset switch may be configured to reset the sub pixel in response to a reset signal.

At least one other example embodiment is directed to an image sensor including: a sub pixel array including at least one sub pixel, wherein the output signal from the sub pixel is a comparison signal; and a counter configured to count the comparison signal output from the sub pixel. The sub pixel includes: a photodetector configured to output an electrical signal based on a detected amount of photons; and a column line output circuit configured to generate an output signal based on the electrical signal, the output signal being one of a current from a current source and the comparison signal indicative of binary output data.

At least one other example embodiment is directed to an image sensor including: a sub pixel array including at least one sub pixel, wherein the output from the sub pixel is a current; and an analog to digital converter configured to convert the current from the sub pixel into a digital signal. In this example, sub pixel includes: a photodetector configured to output an electrical signal based on a detected amount of photons; and a column line output circuit configured to generate an output signal based on the electrical signal, the output signal being one of a current from a current source and the comparison signal indicative of binary output data.

### BRIEF DESCRIPTION OF THE DRAWINGS

FIG. 1 is a block diagram depicting an image sensor according to an example embodiment of inventive concepts;

FIG. 2 is a block diagram of an example embodiment of the sub pixel array illustrated in FIG. 1;

FIG. 3 is a block diagram depicting an example embodiment of a sub pixel illustrated in FIG. 2;

FIG. 4 is a block diagram depicting another example embodiment of the sub pixel illustrated in FIG. 2;

FIG. 5 is a block diagram depicting still another example embodiment of the sub pixel illustrated in FIG. 2;

FIG. 6 is a block diagram depicting an example embodiment of a peripheral circuit illustrated in FIG. 1;

FIG. 7 is a block diagram depicting another example embodiment of the peripheral circuit illustrated in FIG. 1;

FIG. 8 is a block diagram depicting still another example embodiment of the peripheral circuit illustrated in FIG. 1;

FIG. 9 is a block diagram depicting still another example embodiment of the peripheral circuit illustrated in FIG. 1;

FIG. 10 is a block diagram depicting still another example embodiment of the peripheral circuit illustrated in FIG. 1;

FIG. 11 is a block diagram depicting an example embodiment of an image sensing system including the image sensor illustrated in FIG. 1;

FIG. 12 is a block diagram depicting another example embodiment of the image sensing system including the image sensor illustrated in FIG. 1; and

FIG. 13 is a block diagram of a wafer stack for explaining a method for manufacturing the image sensor illustrated in FIG. 1.

### DETAILED DESCRIPTION

Various example embodiments will be described more fully with reference to the accompanying drawings, in which some example embodiments are shown. The present inventive concept may, however, be embodied in many different forms and should not be construed as limited to the embodiments set forth herein. Rather, these embodiments are provided so that this disclosure will be thorough and complete, and will fully convey the scope of the present inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures and techniques may be shown without unnecessary detail in order to avoid obscuring example embodiments.

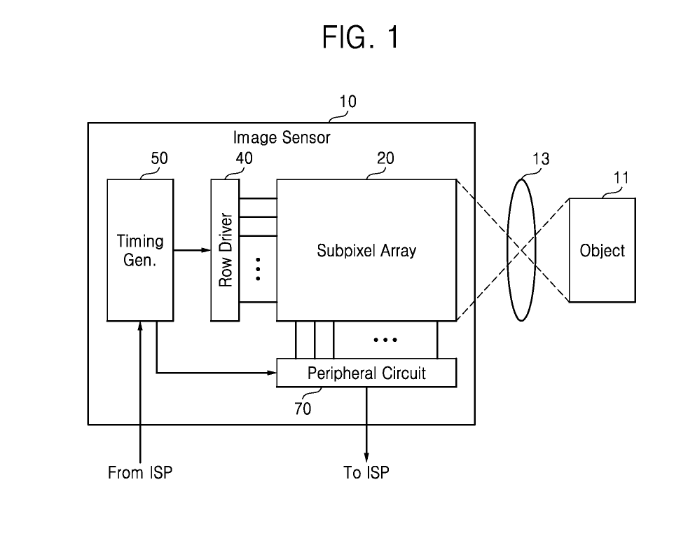

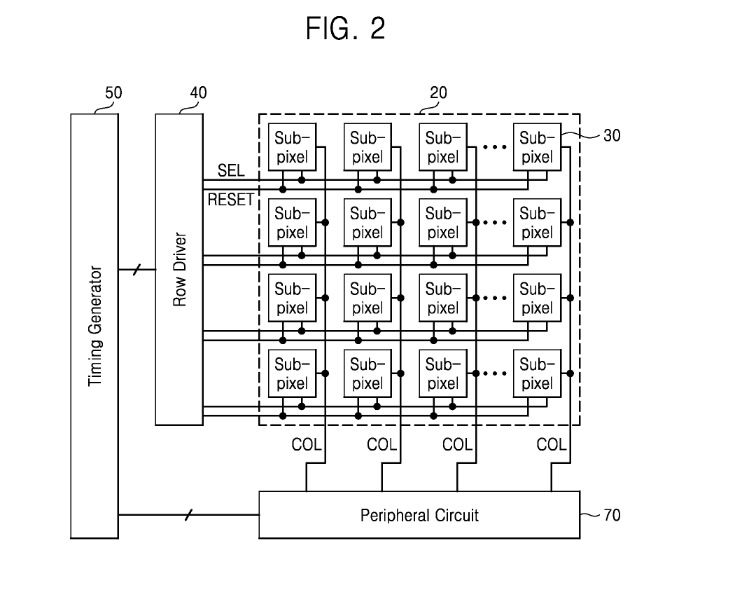

FIG. 1 is a block diagram depicting an image sensor according to an example embodiment of inventive concepts. FIG. 2 is a block diagram of an example embodiment of the sub pixel array illustrated in FIG. 1.

Referring to FIG. 1, an image sensor 10 generates image data for an object 11 taken (shot) or captured through an optical lens 13. The image sensor 10 includes a sub pixel array 20, a row driver 40, a timing generator 50, and a peripheral circuit 70.

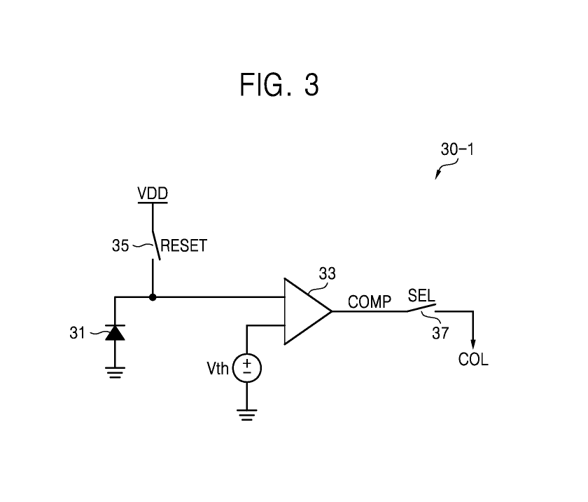

Referring to FIGS. 1 and 2, the sub pixel array 20 includes a plurality of sub pixels 30 arranged in a matrix form. According to an example embodiment, a sub pixel may be referred to as a jot. A sub-pixel pitch is smaller than a pixel pitch in a conventional image sensor. The sub pixels 30 do not include a transfer gate or a floating diffusion region. A structure and an operation of each of the plurality of sub pixels 30 will be described in more detail later with regard to FIGS. 3 to 5.

A row driver 40 drives a plurality of control signals for controlling an operation of each of the plurality of sub pixels 30 according to a control of the timing generator 50 to the sub pixel array 20. For example, the plurality of control signals include a selection signal SEL for selecting each of the plurality of sub pixels 30 and a reset signal RESET for resetting each of the plurality of sub pixels 30.

The timing generator 50 controls an operation of the row driver 40 and the peripheral circuit 70 according to an image signal processor (not shown). The peripheral circuit 70 includes several components (e.g., a memory or a readout circuit) for processing signals output from the sub pixel array 20.

FIG. 3 is a block diagram depicting an example embodiment of the sub pixel illustrated in FIG. 2.

Referring to FIGS. 1 to 3, a sub pixel 30-1 includes a photodetector 31, a comparator 33, a reset switch 35, and a selection switch 37.

The sub pixel 30-1 has a binary output. For example, an output of the sub pixel 30-1 is ‘1’ or ‘0’.

The photodetector 31 detects a certain amount of photons, and outputs an electrical signal corresponding to a certain amount of photoelectrons. The certain amount of photoelectrons is generated by the detected photons. For example, the photodetector 31 may be embodied in a photodiode, a photo transistor, a pinned photodiode, etc.

The comparator 33 compares a threshold signal Vth with the electrical signal, and outputs a comparison signal COMP according to a result of the comparison. For example, when the threshold voltage Vth is greater than or equal to the electrical signal, the comparison signal COMP is ‘1’. When the threshold signal Vth is less than the electrical signal, the comparison signal COMP is ‘0’. According to at least this example embodiment, the comparator 33 may detect one photon output from the photodetector 31 according to a value of the threshold signal Vth.

As discussed herein the comparator 33 may also be referred to as a column line output circuit.

The reset switch 35 is connected between a terminal of the photodetector 31 and a node supplying a supply voltage VDD. The reset switch 35 is switched in response to a reset signal RESET. For example, the reset switch 35 may be embodied as a transistor or similar switching device. The reset signal RESET is output from the row driver 40.

The selection switch 37 is connected between an output terminal of the comparator 33 and a column line COL. The selection switch 37 outputs a comparison signal COMP to a column line COL in response to a selection signal SEL. For example, the selection switch 37 may be embodied as a transistor or similar switching device. The selection signal SEL is output from the row driver 40.

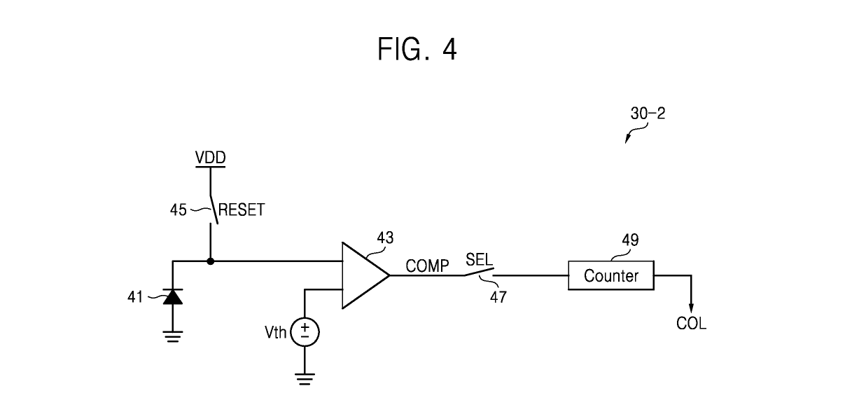

FIG. 4 is a block diagram depicting another example embodiment of the sub pixel illustrated in FIG. 2.

Referring to FIGS. 1, 2, and 4, a sub pixel 30-2 includes a photodetector 41, a comparator 43, a reset switch 45, a selection switch 47, and a counter 49.

The photodetector 41, the comparator 43, the reset switch 45, and the selection switch 47 illustrated in FIG. 4 have operations and functions similar or substantially similar to the photodetector 31, the comparator 33, the reset switch 35, and the selection switch 37 illustrated in FIG. 3, so that detailed explanation for this will be omitted.

The counter 49 counts a comparison signal COMP. The comparator 43 outputs a plurality of comparison signals with time. The counter 49 counts the comparison signals output from the comparator 43. The counter 49 may be embodied by using register-type circuits such as flip-flops or the like.

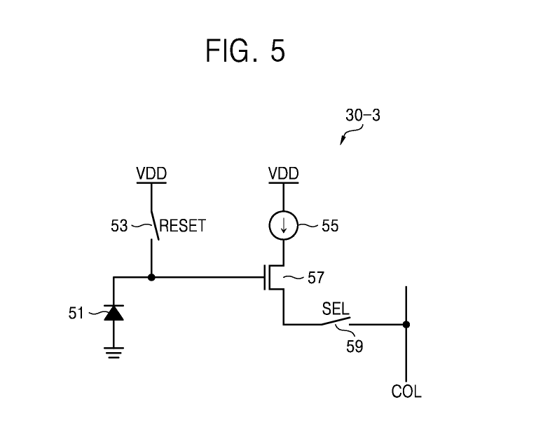

FIG. 5 is a block diagram depicting still another example embodiment of the sub pixel illustrated in FIG. 2.

Referring to FIGS. 1, 2, and 5, a sub pixel 30-3 includes a photodetector 51, a reset switch 53, a current source 55, a control circuit 57, and a selection switch 59.

The photodetector 51 detects a certain amount of photons and outputs an electrical signal corresponding to a certain amount of photoelectrons. For example, the photodetector 51 may be embodied as a photo diode, a photo transistor, a pinned photodiode, etc.

The reset switch 53 is connected between a terminal of the photodetector 51 and a node supplying a supply voltage VDD. The reset switch 53 is switched in response to a reset signal RESET. For example, the reset switch 53 may be embodied as a transistor or similar switching device. The reset signal RESET is output from the row driver 40. The current source 55 generates a current.

The control circuit 57 outputs the current to the selection switch 59 in response to the electrical signal output from the photodetector 51. For example, the control circuit 57 may be embodied as a transistor or similar switching device. The selection switch 59 is connected between a terminal of the control circuit 57 and a column line COL. The selection switch 59 outputs the current to the column line COL in response to a selection signal SEL. For example, the selection switch 59 may be embodied as a transistor or similar switching device. The selection signal SEL is output from the row driver 40.

As discussed herein the control circuit 57 and the current source 55 may also be referred to as a column line output circuit.

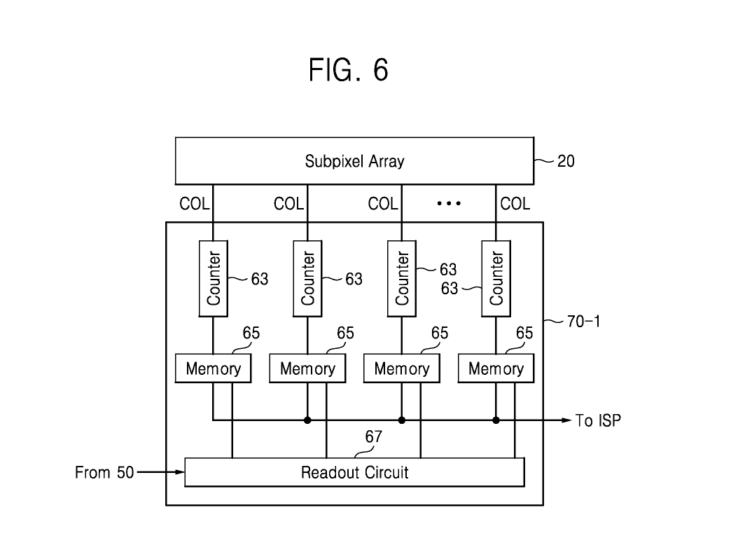

FIG. 6 is a block diagram depicting an example embodiment of the peripheral circuit illustrated in FIG. 1.

Referring to FIGS. 1 to 3, and 6, a peripheral circuit 70-1 includes a plurality of counters 63, a plurality of memories 65, and a readout circuit 67.

Each of the plurality of counters 63 counts a comparison signal output from each of the sub pixels 30 through the column line COL. When each of the sub pixels 30 outputs a plurality of comparison signals with time, each of the counters 63 counts comparison signals output through each column line COL. According to an example embodiment, the plurality of counters 63 may perform a counting operation in response to a control signal output from the timing generator 50.

Each of the plurality of memories 65 stores a counter value output from each of the plurality of counters 63. According to an example embodiment, the plurality of memories 65 may store a counter value in response to a control signal output from the timing generator 50.

The readout circuit 67 controls the plurality of memories 65 so as to output, to an image signal processor, the counter value stored in each of the plurality of memories 65 according to a control of the timing generator 50. That is, for example, the readout circuit 67 outputs, to the image signal processor, the counter value, stored in one of the plurality of memories 65 according to a control of the timing generator 50. According to an example embodiment, the readout circuit 67 may include a column decoder, a column driver, and an output buffer which are not illustrated.

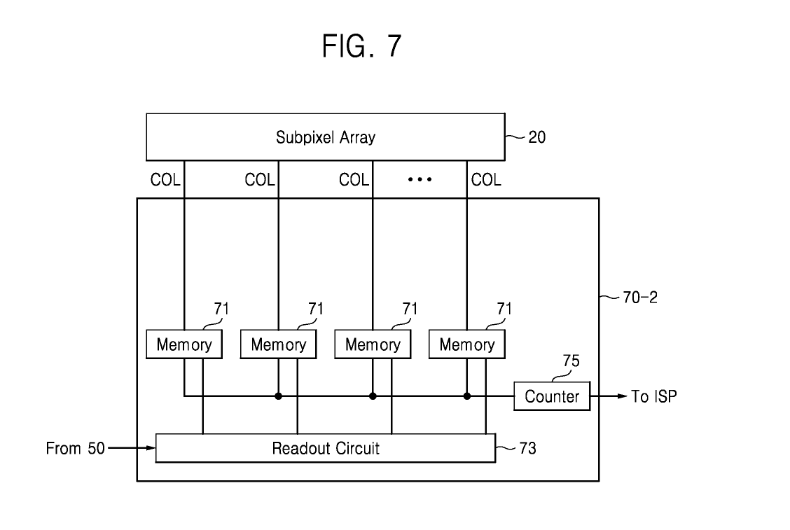

FIG. 7 is a block diagram depicting another example embodiment of the peripheral circuit illustrated in FIG. 1.

Referring to FIGS. 1 to 3, and 7, a peripheral circuit 70-2 includes a plurality of memories 71, a readout circuit 73, and a counter 75.

Each of the plurality of memories 71 stores a comparison signal output from each of the sub pixels 30. When each of the sub pixels 30 outputs a plurality of comparison signals with time, each of the plurality of memories 71 stores comparison signals output from each of the sub pixels 30. Each of the comparison signals is a binary output. According to an example embodiment, the plurality of memories 71 may store a counter value in response to a control signal output from the timing generator 50.

The readout circuit 73 controls the plurality of memories 71 so as to output, to the counter 75, the comparison signals stored in each of the plurality of memories 71 according to a control of the timing generator 50. That is, for example, the readout circuit 73 outputs, to the counter 75, the comparison signals stored in one of the plurality of memories 71 according to a control of the timing generator 50.

The counter 75 counts the comparison signals and outputs a counting value to an image signal processor. According to an example embodiment, the counter 75 may perform a counting operation in response to a control signal output from the timing generator 50.

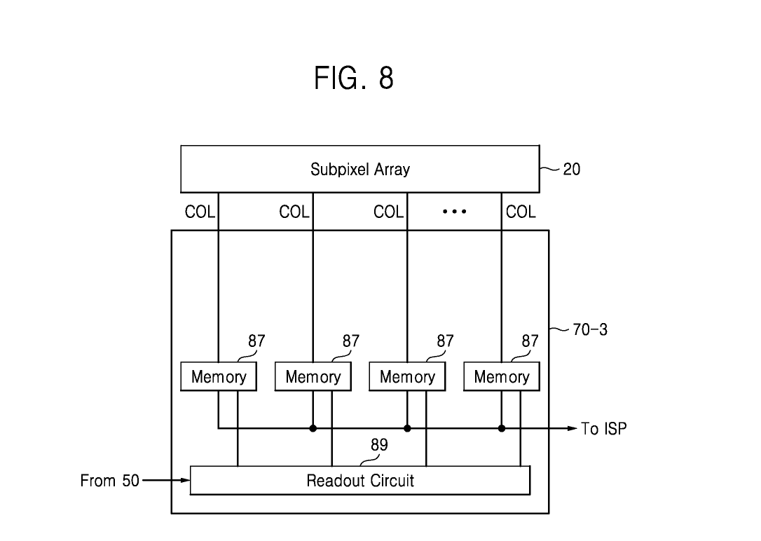

FIG. 8 is a block diagram depicting still another example embodiment of the peripheral circuit illustrated in FIG. 1.

Referring to FIGS. 1, 2, 4, and 8, a peripheral circuit 70-3 includes a plurality of memories 87 and a readout circuit 89.

Each of the plurality of memories 87 stores a counting value output from each of the sub pixels 30. According to an example embodiment, the plurality of memories 87 may store a counter value in response to a control signal output from the timing generator 50.

The readout circuit 89 controls the plurality of memories 87 so as to output, to an image signal processor, the counting value stored in each of the plurality of memories 87 according to a control of the timing generator 50. That is, for example, the readout circuit 89 outputs, to the image signal processor, the counting value stored in one of the plurality of memories 87 according to a control of the timing generator 50.

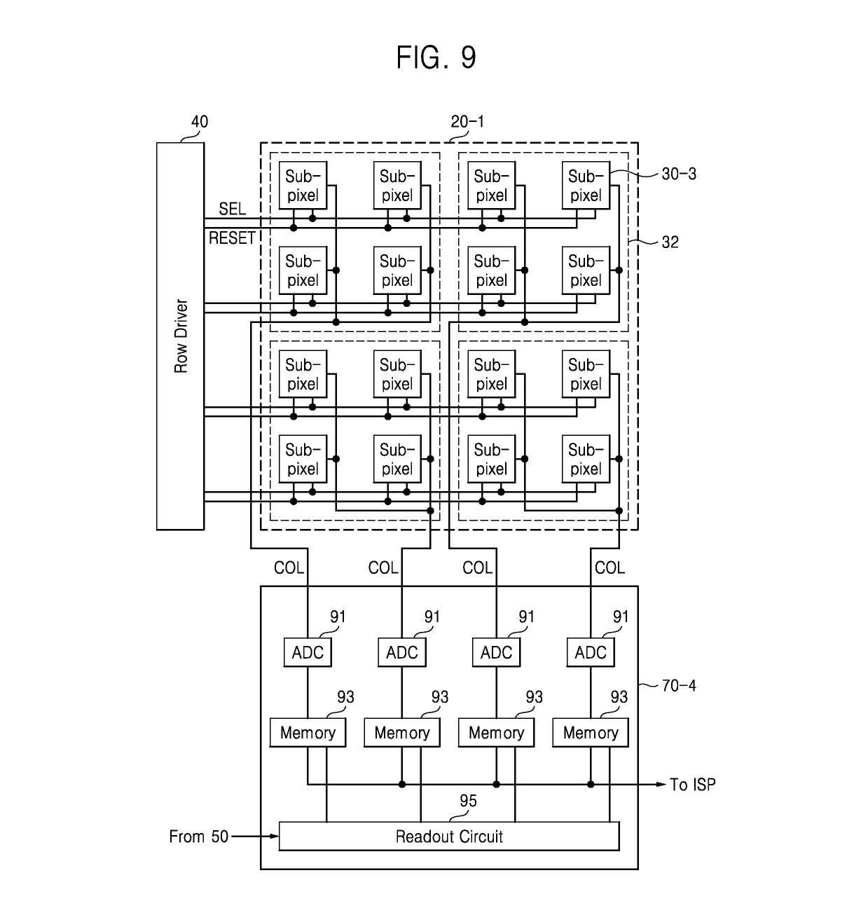

FIG. 9 is a block diagram depicting still another example embodiment of the peripheral circuit illustrated in FIG. 1.

Referring to FIGS. 1, 2, 5, and 9, a sub pixel array 20-1 is an example embodiment of the sub-pixel array 20 illustrated in FIG. 1. The sub pixel array 20-1 may include a plurality of pixels 32. Each of the pixels 32 is a group of a plurality of sub pixels 30-3. It is illustrated that a pixel 32 of FIG. 9 includes four sub pixels 30-3; however, the number of sub pixels composing one pixel 32 may vary according to example embodiments.

A peripheral circuit 70-4 includes a plurality of analog to digital converters 91, a plurality of memories 93, and a readout circuit 95.

Each of the plurality of analog to digital converters 91 converts a current output from each of the pixels 32 into a digital signal. A current output from each of the pixels 32 is a sum of currents output from the sub pixels 30-3. It becomes unnecessary to individually calculate each output of the sub pixels 30-3 by converting a current output from the one pixel 32 into a digital signal.

Each of the plurality of memories 93 stores a digital signal output from each of the plurality of analog to digital converters 91. According to an example embodiment, the plurality of memories 93 may store a counter value in response to a control signal output from the timing generator 50.

The readout circuit 95 controls the plurality of memories 93 so as to output, to an image signal processor, the digital signal stored in each of the plurality of memories 93 according to a control of the timing generator 50.

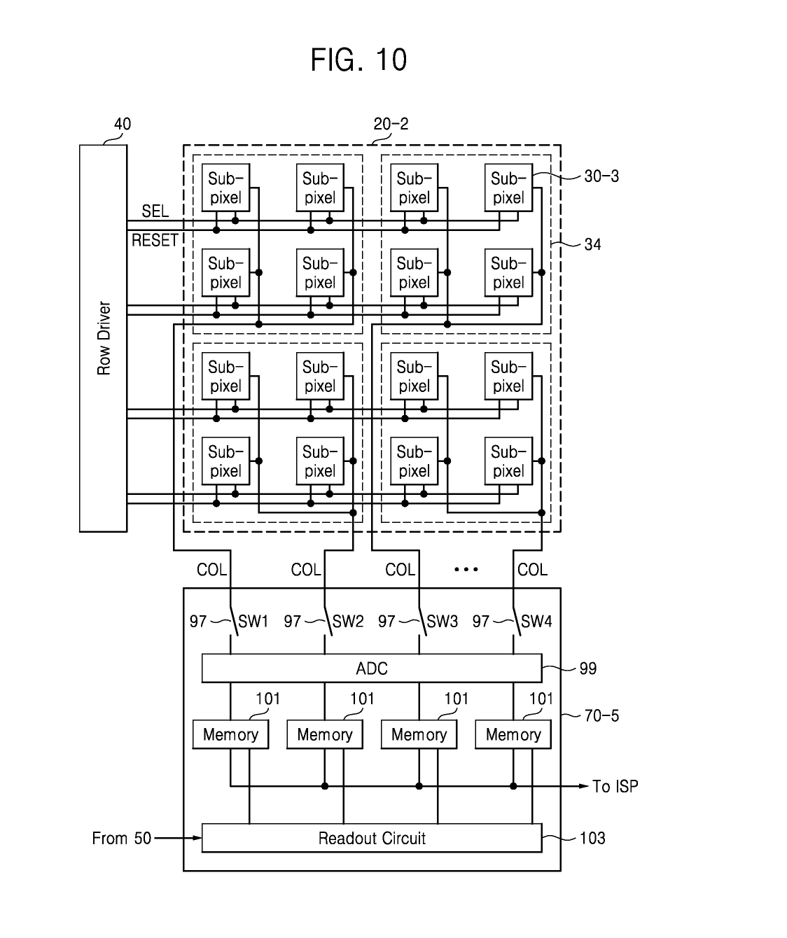

FIG. 10 is a block diagram depicting still another example embodiment of the peripheral circuit illustrated in FIG. 1.

Referring to FIGS. 1, 2, 5, and 10, a sub pixel array 20-2 is an example embodiment of the sub pixel array 20 illustrated in FIG. 1. The sub pixel array 20-2 may include a plurality of pixels 34. Each of the pixels 34 is a set of the plurality of sub pixels 30-3.

A peripheral circuit 70-5 includes a plurality of switches 97, an analog to digital converter 99, a plurality of memories 101, and a readout circuit 103. The plurality of switches 97 is switched in response to switching signals SW1 to SW4 generated from the timing generator 50.

The analog to digital converter 99 converts a current output from each of the pixels 34 into a digital signal. A current output from each of the pixels 34 is a set of currents output from the sub pixels 30-3. It is illustrated that the pixel 34 of FIG. 10 includes four sub pixels 30-3; however, the number of sub pixels composing one pixel 34 may vary according to example embodiments. The analog to digital converter 99 may be embodied as a successive approximation analog to digital converter (ADC).

Each of the plurality of memories 101 stores a digital signal output from the analog to digital converter 99. According to an example embodiment, the plurality of memories 101 may store a counter value in response to a control signal output from the timing generator 50.

The readout circuit 103 controls the plurality of memories 101 so as to output, to an image signal processor, the digital signal stored in each of the plurality of memories 101 according to a control of the timing generator 50.

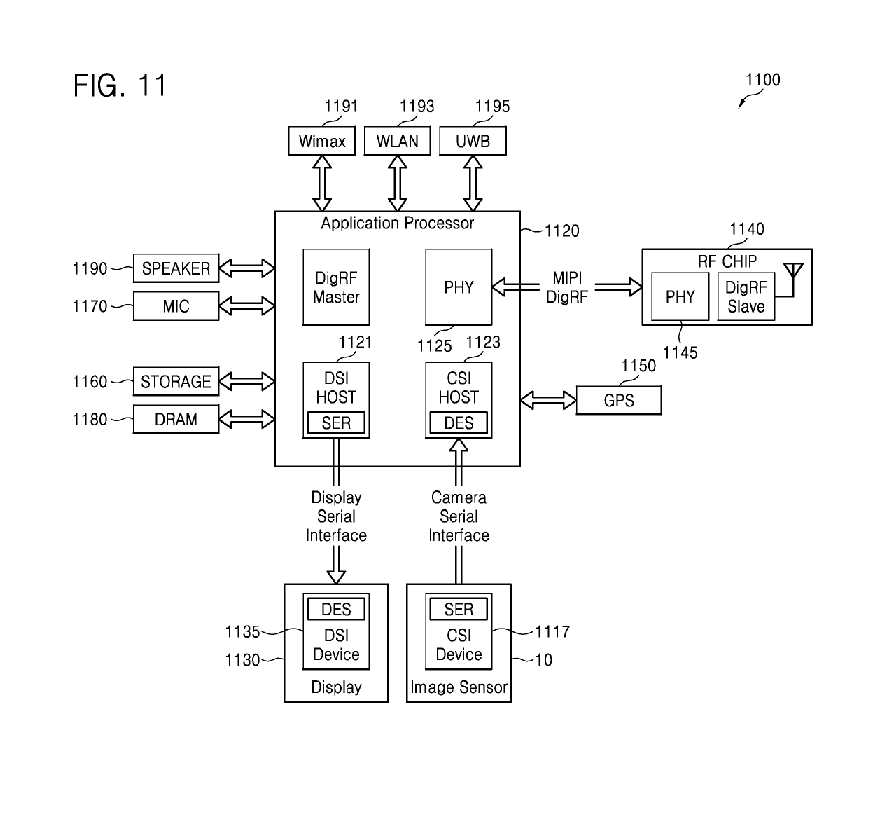

FIG. 11 is a block diagram depicting an example embodiment of an image sensing system including the image sensor illustrated in FIG. 1.

Referring to FIGS. 1 and 11, an image sensing system 1100 may be embodied in a data processing device, which may use or support a mobile industry processor interface (MIPI®), such as a personal digital assistant (PDA), a portable multimedia player (PMP), an internet protocol television (IPTV), a tablet PC, a smart phone, etc.

The image sensing system 1100 includes an image sensor 10, an application processor 1120, and a display 1130.

An image signal processor (not shown) for processing an image data output from the image sensor 10 may be embodied in one chip. According to an example embodiment, the image signal processor may be embodied in the application processor 1120.

A camera serial interface (CSI) host 1123 embodied in the application processor 1120 may perform a serial communication with a CSI device 1117 of a camera module 1110 through a camera serial interface. Here, for example, the CSI host 1123 may include a deserializer (DES), and the CSI device 1117 may include a serializer (SER).

A DSI host 1121 embodied in the application processor 1120 may perform a serial communication with a DSI device 1135 of the display 1130 through a display serial interface (DSI). Here, for example, the DSI host 1121 may include a serializer (SER), and the DSI device 1135 may include a deserializer (DES).

According to an example embodiment, the image sensing system 1100 may further include a radio frequency (RF) chip 1140 communicating with the application processor 1120. A PHYsical layer (PHY) 1125 included in the application processor and a PHY 1145 included in the RF chip 1140 may transmit or receive data according to MIPI DigRF.

According to an example embodiment, the image sensing system 1100 may further include a global positioning system (GPS) receiver 1150, a storage 1160, a microphone (MIC) 1170, a dynamic random access memory (DRAM) 1180, and a speaker 1190.

The image sensing system 1100 may perform a communication by using a world interoperability for microwave access (WiMAX) 1191, a wireless local area network (WLAN) 1193, and/or ultra wideband (UWB) 1195.

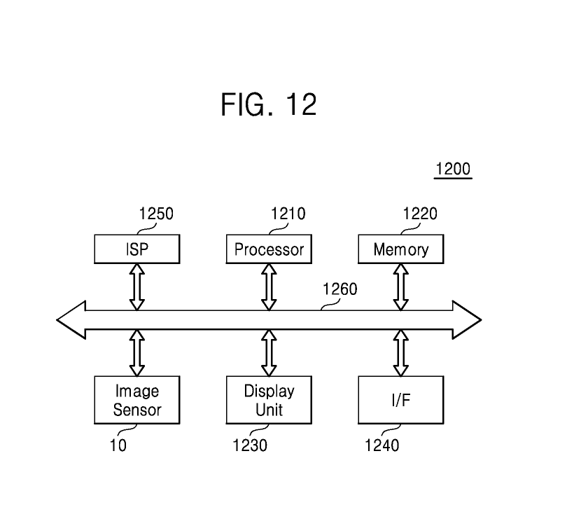

FIG. 12 is a block diagram depicting another example embodiment of the image sensing system including the image sensor illustrated in FIG. 1.

Referring to FIGS. 1 and 12, an image sensing system 1200 may include the image sensor 10, a processor 1210, a memory 1220, a display unit 1230, an interface 1240, and an image signal processor 1250.

The processor 1210 may control an operation of the image sensor 10. The image signal processor 1250 performs several operations (e.g., image scaling and image enhancement) on a signal output from the image sensor 10. According to an example embodiment, the image sensor 10 and the image signal processor 1250 may be embodied in one chip.

The memory 1220 may store commands for controlling an operation of the image sensor 10 through a bus 1260 and an image generated in the processor 1210 or the image signal processor 1250, and the processor 1210 may execute commands stored in the memory 1220. The memory 1220 may be embodied in a non-volatile memory, such as a flash memory or the like.

The display unit 1230 may receive an image from the processor 1210 or the memory 1220, and display the image through a display, such as a Liquid Crystal Display (LCD), a light-emitting diode (LED) display, an organic LED (OLED) display, an active matrix organic light-emitting diodes (AMOLED) display, a flexible display, etc.

The interface 1240 may be embodied as an interface for inputting/outputting an image. According to an example embodiment, the interface 1240 may be embodied as a wireless interface.

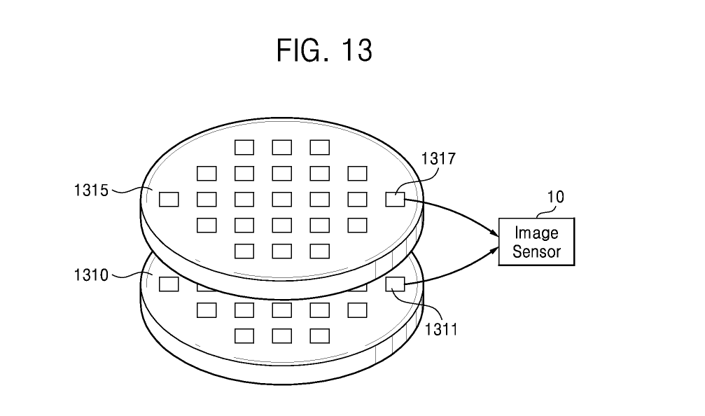

FIG. 13 is a block diagram of a wafer stack for explaining a method for manufacturing the image sensor illustrated in FIG. 1.

Referring to FIGS. 1 and 13, a first wafer 1315 includes a plurality of dies 1317. Each of the plurality of dies 1317 may be the sub pixel array 20 illustrated in FIG. 1. A second wafer 1310 includes a plurality of dies 1311. Each of the plurality of dies 1311 may be the counter 63 illustrated in FIG. 6. According to an example embodiment, each of the plurality of dies 1311 may be the analog to digital converter 91 illustrated in FIG. 9. In this example, the image sensor 10 illustrated in FIG. 1 may be embodied in a wafer stack.

A sub pixel according to an example embodiment of inventive concepts, an image sensor having the same, and an image sensing system may solve problems arising as image sensor size is reduced by providing a new type of a sub pixel structure.

Although a few example embodiments of inventive concepts have been shown and described, it will be appreciated by those skilled in the art that changes may be made in these example embodiments without departing from the principles and spirit of the general inventive concept, the scope of which is defined in the appended claims and their equivalents.

What is claimed is:

1. A sub pixel comprising:
a photodetector configured to detect a certain amount of photons and output an electrical signal corresponding to photoelectrons generated by the detected photons; and
a comparator configured to compare a threshold signal with the electrical signal and output a comparison signal based on a result of the comparison.

2. The sub pixel of claim 1, further comprising:
a counter configured to count the comparison signal.

3. The sub pixel of claim 1, further comprising:
a selection switch configured to output the comparison signal in response to a selection signal.

4. The sub pixel of claim 1, wherein the comparator is configured to detect a photon output from the photodetector according to a value of the threshold signal.

5. An image sensor comprising:
a sub pixel array including the sub pixel of claim 1; and
a counter configured to count the comparison signal output from the sub pixel.

6. The image sensor of claim 5, further comprising:
a memory configured to store a counter value output from the counter; and
a readout circuit configured to control the memory to output the counter value.

7. The image sensor of claim 5, wherein the sub pixel array and the counter are embodied in different wafers.

8. An image sensing system comprising:
the image sensor of claim 5; and
an image signal processor configured to process a signal output from the image sensor.

9. The image sensing system of claim 8, wherein the image sensing system is a smart phone or a tablet PC.

10. A sub pixel comprising:
a photodetector configured to detect a certain amount of photons and output an electrical signal corresponding to photoelectrons generated by the detected photons;
a current source configured to generate a current; and
a control circuit configured to output the current in response to the electrical signal.

11. An image sensor comprising:
a sub pixel array including the sub pixel of claim 10; and
an analog to digital converter configured to convert the current output from the sub pixel into a digital signal.

12. The image sensor of claim 11, wherein the sub pixel array and the analog to digital converter are embodied in different wafers.

13. An image sensing system comprising:
the image sensor of claim 11; and
an image signal processor configured to process the digital signal output from the image sensor.

14. The image sensing system of claim 13, wherein the image sensing system is a smart phone or a tablet PC.

15. A sub pixel comprising:
a photodetector configured to output an electrical signal based on a detected amount of photons; and
a column line output circuit configured to generate an output signal based on the electrical signal, the output signal being one of a current from a current source and a comparison signal indicative of binary output data.

16. The sub pixel of claim 15, wherein the output signal is the comparison signal, and the sub pixel further includes,
a counter coupled between the column line output circuit and a column line, the counter being configured to count the comparison signal.

17. The sub pixel of claim 15, further comprising:
a selection switch coupled between the column line output circuit and a column line, the selection switch being configured to output the output signal in response to a selection signal.

18. The sub pixel of claim 15, further comprising:
a reset switch coupled between the photodetector and the column line output circuit, the reset switch being configured to reset the sub pixel in response to a reset signal.

19. An image sensor comprising:
a sub pixel array including the sub pixel of claim 15, the output signal being the comparison signal; and
a counter configured to count the comparison signal output from the sub pixel.
